(19) United States
(12) Patent Application Publication
(10) Pub. No.: US 2026/0369194 A1
(43) Pub. Date: Nov. 19, 2026

(54) DISPLAY DEVICE, METHOD FOR INSPECTING DISPLAY DEVICE AND ELECTRONIC DEVICE INCLUDING DISPLAY DEVICE

(71) Applicant: SAMSUNG DISPLAY CO., LTD., YONGIN-SI (KR)

(72) Inventor: Tae Jin HWANG, Yongin-si (KR)

(21) Appl. No.: 19/445,698

(22) Filed: Jan. 12, 2026

(30) Foreign Application Priority Data
May 19, 2025 (KR) 10-2025-0064530

(51) Int. Cl. G09G 3/00; H10K 59/80; H10K 71/70

(52) U.S. Cl. CPC G09G 3/006; H10K 59/872; H10K 59/873; H10K 71/70; G09G 2330/12

(57) ABSTRACT

A display device including a display panel, a cover window disposed on the display panel, a panel support , a protective coating layer configured to protect at least a part of the display panel, and at least one test coating layer disposed on at least one of the cover window and the panel support, the display panel being disposed on the panel support.

### CROSS-REFERENCE TO RELATED APPLICATION.S

This application claims priority under 35 U.S.C. § 119 to and benefits from Korean Patent Application No. 10-2025-0064530 filed on May. 19, 2025 in the Korean Intellectual Property Office, the entire contents of which is incorporated by reference herein.

### TECHNICAL FIELD

The disclosure relates to a display device, a method for inspecting a display device, and an electronic device including a display device.

### DISCUSSION OF THE RELATED ART

Typically, electronic devices such as a smart phone, a tablet, a digital camera, a laptop computer, a navigation device and a smart TV may include an organic light-emitting display device for displaying images.

Organic light-emitting display devices have advantages such as good luminance, low driving voltage, fast response speed and a wide range of color reproduction, and accordingly are being employed by a variety of electronic devices including smart phones. An organic light-emitting display device may include a display panel including a plurality of pixels, and circuitry configured to supply signals to the display panel.

The display panel may be implemented as a substrate on which signal lines for transmitting signals for producing images and switching elements for driving pixels are formed. A protective coating layer may be disposed on the rear side of the display panel to protect the display panel.

### SUMMARY

Embodiments of the disclosure provide a display device capable of efficiently inspecting defects in a protective coating layer protecting a display panel, a method for inspecting a display device, and an electronic device including the display device.

According to an embodiment of the disclosure, a display device includes a display panel, a cover window disposed on the display panel, a panel support, the display panel being disposed on the panel support, a protective coating layer configured to protect at least a part of the display panel, and at least one test coating layer disposed on at least one of the cover window and the panel support.

According to an embodiment of the disclosure, the display panel may be divided into a first area that may overlap the panel support in a plan view, and a second area that may not overlap the panel support in a plan view, the protective coating layer may be configured to protect the second area of the display panel.

According to an embodiment of the disclosure, the at least one test coating layer may be disposed on the panel support.

According to an embodiment of the disclosure, the at least one test coating layer may include a plurality of test coating layers, and the plurality of test coating layers may be disposed along an edge portion of the panel support while being spaced apart from one another.

According to an embodiment of the disclosure, the panel support may have a polygonal shape having a plurality of sides in a plan view, and the plurality of test coating layers may be disposed at corner portions of the panel support, respectively.

According to an embodiment of the disclosure, the at least one test coating layer may be disposed on the cover window.

According to an embodiment of the disclosure, the at least one test coating layer may include a plurality of test coating layers, and the plurality of test coating layers may be disposed along an edge portion of the cover window while being spaced apart from one another.

According to an embodiment of the disclosure, the cover window may have a polygonal shape having a plurality of sides in a plan view, and the test coating layers may be disposed at corner portions of the cover window, respectively.

According to an embodiment of the disclosure, a lower surface of the protective coating layer and a lower surface of the panel support may be coplanar.

According to an embodiment of the disclosure, the protective coating layer and the at least one test coating layer may include a same material.

According to an embodiment of the disclosure, a method for inspecting a display device includes capturing an image of at least one test coating layer by a camera of an inspector, determining whether the at least one test coating layer is defective by analyzing the captured image of the at least one test coating layer by an analyzer of the inspector, capturing an image of a protective coating layer by the camera, and determining whether the protective coating layer is defective by analyzing the captured image of the protective coating layer by the analyzer.

According to an embodiment of the disclosure, the inspector may further include an actuator that moves the camera.

According to an embodiment of the disclosure, the at least one test coating layer may include a plurality of test coating layers, the plurality of test coating layers may be spaced apart from one another, and the capturing of the image of the at least one test coating layer may include moving the camera over each of the plurality of test coating layers in a plan view by the actuator.

According to an embodiment of the disclosure, the display device may include a display panel, the protective coating layer may be disposed along an edge portion of the display panel, and the capturing of the image of the protective coating layer may include moving the camera over the protective coating layer in a plan view by the actuator.

According to an embodiment of the disclosure, the capturing of the image of the protective coating layer may be conducted upon determination that the test coating layer is not defective.

According to an embodiment of the disclosure, an electronic device includes a display panel, a cover window disposed on the display panel, a panel support, the display panel is disposed on the panel support in a plan view, a protective coating layer configured to protect at least a part of the display panel, and at least one test coating layer disposed on at least one of the cover window and the panel support.

According to an embodiment of the disclosure, the display panel may be divided into a first area that overlaps the panel support in a plan view, and a second area that does not overlap the panel support in a plan view, the protective coating layer may be configured to protect the second area of the display panel.

According to an embodiment of the disclosure, the at least one test coating layer may include a plurality of test coating layers, and the plurality of test coating layers may be disposed along an edge portion of the panel support while being spaced apart from one another.

According to an embodiment of the disclosure, the at least one test coating layer may include a plurality of test coating layers, and the plurality of test coating layers may be disposed along an edge portion of the cover window while being spaced apart from one another.

According to an embodiment of the disclosure, the electronic device may further include at least one processor, a memory in which data of the at least one of the display panel and the at least one processor may be stored, and a power module configured to supply power to the display panel, the at least one processor and the memory.

According to an embodiment of the disclosure, a test coating layer may be disposed on a panel support or a cover window of a display device, and the test coating layer may be inspected before the protective coating layer is inspected. As a result, it may be possible to efficiently inspect whether the protective coating layer protecting a display panel is defective or not.

The effects according to the embodiments of the disclosure are not necessarily limited to those mentioned above and more various effects are included in the following description of the disclosure.

### BRIEF DESCRIPTION OF THE DRAWINGS

The above and other aspects and features of the disclosure will become more apparent by describing in detail example embodiments thereof with reference to the attached drawings, in which:

FIG. 1 is a plan view of a display device according to an embodiment of the disclosure.

FIG. 2 is a bottom view of the display device shown in FIG. 1.

FIG. 3 is a cross-sectional view taken along line A – A' of FIG. 2.

FIG. 4 is an exploded cross-sectional view of the display panel of FIG. 3.

FIG. 5 is a bottom view showing another example of the display device shown in FIG. 2.

FIG. 6 is a cross-sectional view taken along line B – B' of FIG. 5.

FIG. 7 is a flowchart for illustrating a method for inspecting a display device according to an embodiment of the disclosure.

FIG. 8 is a view showing an inspector inspecting a display device.

FIG. 9 is a view showing capture areas where the camera of the inspector captures images of test coating layers of a display device.

FIG. 10 is a view showing capture areas where the camera of the inspector captures images of a protective coating layer of a display device.

FIG. 11 is a view showing another example of FIG. 8.

FIG. 12 is a view showing capture areas where the camera of the inspector captures images of test coating layers of a display device in the example of FIG. 11.

FIG. 13 is a view showing capture areas where the camera of the inspector captures images of a protective coating layer of a display device in the example of FIG. 11.

FIG. 14 is a block diagram of an electronic device according to an embodiment of the disclosure.

FIG. 15 is a view showing electronic devices according to a variety of embodiments of the disclosure.

### DETAILED DESCRIPTION OF EMBODIMENTS

Advantages and features of the disclosure and methods to achieve them will become apparent from the descriptions of example embodiments hereinbelow with reference to the accompanying drawings. However, the disclosure is not necessarily limited to example embodiments disclosed herein but may be implemented in various different ways. The example embodiments are provided for making the disclosure of the disclosure thorough and for fully conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. While each drawing may represent one or more particular embodiments of the disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the disclosure, for example, to allow for manufacturing limitations and the like.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various example embodiments of the disclosure may be combined partially or totally. As will be clearly appreciated by those skilled in the art, technically various interactions and operations are possible. Various example embodiments can be practiced individually or in combination.

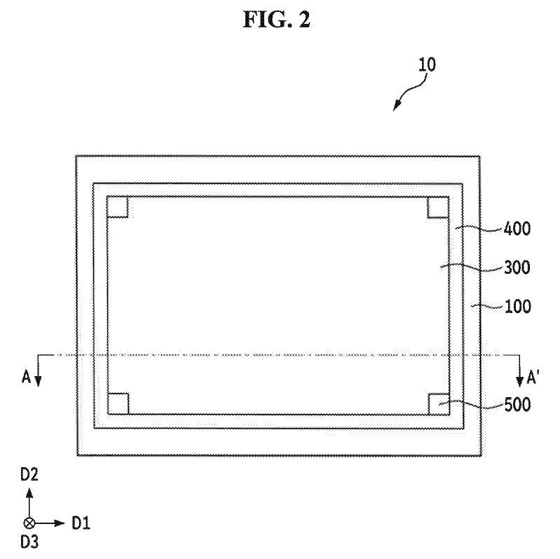

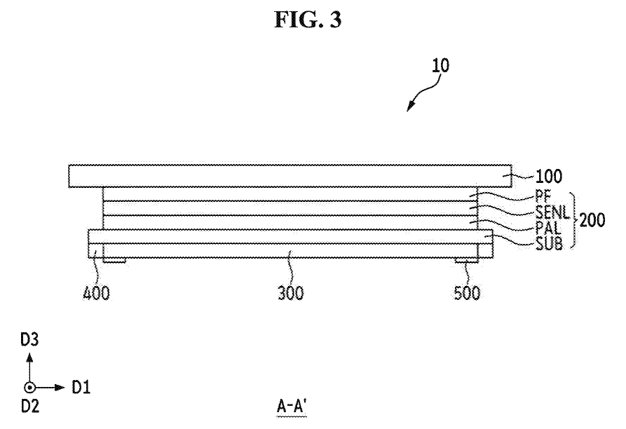

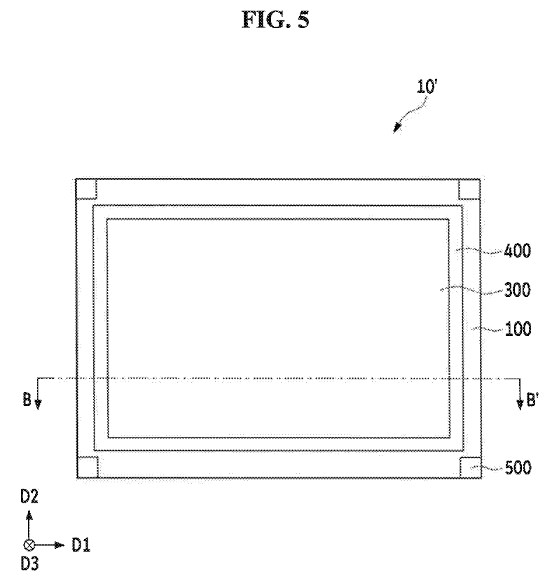

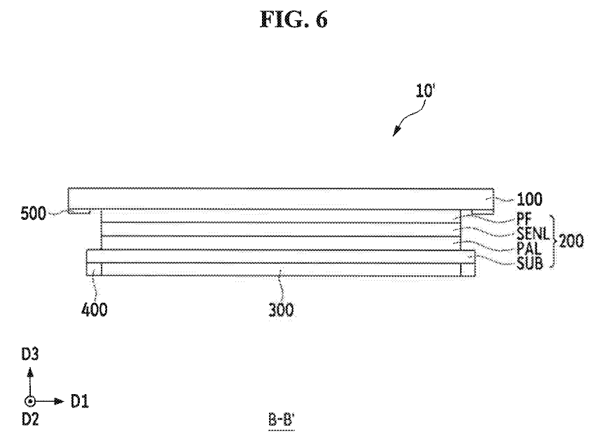

According to embodiments of the disclosure, there is provided a display device, a method of inspecting the display device, and an electronic device that includes the display device. The display device may include a display panel that may include a substrate mounted on a panel support to protect a first area of the display panel. However the panel support may not cover edge portions corresponding to a second area of the substrate of the display panel. Therefore a protective coating layer may be disposed on a lower surface of the edge portions of the substrate to correspond to a second area of the substrate. The protective coating layer may be formed by a screen printing technique. A test coating layer may be formed simultaneously with the protective coating layer. In a first embodiment of FIGS. 2-3, the test coating layer may be formed at corner portions on a lower surface of the panel support, and in a second embodiment of FIGS. 5-6, the test coating layer may be formed at corner portions on a lower side of the cover window.

According to embodiments, a method of inspecting the display device by an inspector may involve determining whether there are defects in the protective coating layer. This can be gleaned by determining whether defects are present in the test coating layers. A camera may capture images of the test coating layers and an analyzer may compare the captured images with images of a non-defective test coating layer preloaded into the inspector to determine whether the test coating layers are defective. If the test coating layers are determined not to be defective, the camera may capture images of the protective coating layer and compare the captured image with images of a non-defective protective coating layer to determine whether the protective coating layer on the display panel is defective. If the test coating layers are determined to be defective, the inspection process may conclude that the protective coating layer is also defective.

Hereinafter, example embodiments of the disclosure will be described in detail with reference to the accompanying drawings.

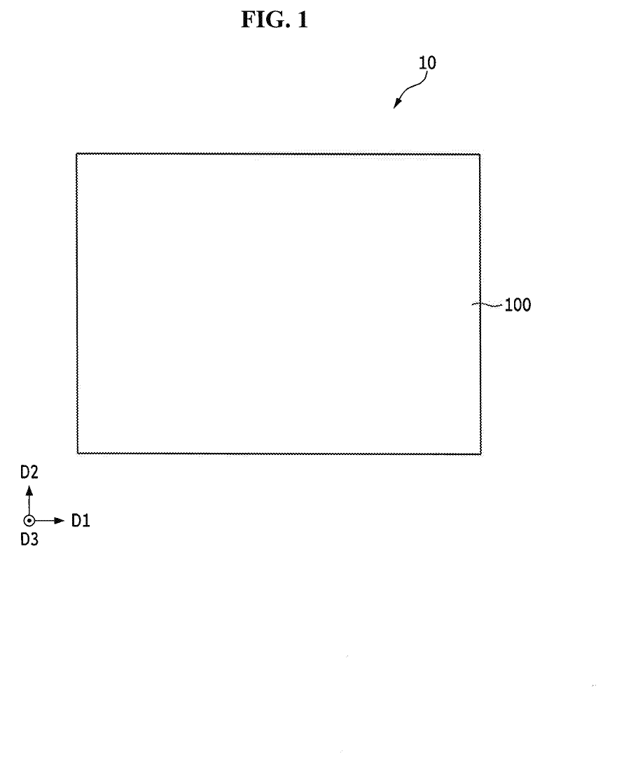

FIG. 1 is a plan view of a display device according to an embodiment of the disclosure. FIG. 2 is a bottom view of the display device shown in FIG. 1. FIG. 3 is a cross-sectional view taken along line A – A' of FIG. 1.

As used herein, a display device 10 according to an example embodiment of the disclosure may be for displaying moving images or still images. The display device 10 may be used as the display screen of portable electronic devices such as a mobile phone, a smart phone, a tablet, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook / laptop computer, a computer monitor, a billboard and the Internet of Things device. For example, the display device 10 may be used as a display screen applied to the center fascia of a vehicle.

The display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro light-emitting display device using micro light-emitting diodes (LED). In the following description, an organic light-emitting display device is described as an example of the display device 10. It is, however, to be understood that the disclosure is not necessarily limited thereto.

The first direction D1 may refer to a direction parallel to a side of the display device 1, for example, the horizontal direction of the display device 10 in a plan view (or ‘when viewed from the top in a thickness direction of the display device’). A second direction D2 may refer to a direction parallel to another side of the display device 10 that intersect the side of the display device 10, for example, the vertical direction of the display device 10 in a plan view. A third direction D3 may refer to the thickness direction of the display device 10.

The display device 10 may have a quadrangular shape, such as a rectangular shape in a plan view. For example, the display device 10 may have a rectangular shape having longer sides in the first direction D1 and shorter sides in the second direction D2 in a plan view. The corners (or ‘corner portions’) where the longer sides in the first direction D1 intersect the shorter sides in the second direction D2 may be rounded with a curvature or may be a right angle. The shape of the display device 10 in a plan view is not necessarily limited to a rectangular shape but may be formed in another polygonal shape, a circular shape, or an elliptical shape.

The display device 10 may include a display area and a non-display area. The shape of the display area may follow the shape of the display device 10 in a plan view. For example, when the display device 10 has a rectangular shape in a plan view, the display area may also have a rectangular shape in a plan view.

The display area may include a plurality of pixels to display images. The non-display area might not include pixels and thus might not display images. The non-display area may be located (or ‘disposed’) around the display area. The non-display area may surround the display area, but the embodiments of the disclosure are not necessarily limited thereto. The display area may be partially surrounded by the non-display area.

Referring to FIGS. 1-3, the display device 10 according to the embodiment of the disclosure may include a cover window 100, a display panel 200, a panel support 300, a protective coating layer 400, and a test coating layer 500.

The cover window 100 may include a material with high light transmittance. The cover window 100 may include a polymer resin such as polyimide or glass. The cover window 100 may be attached onto a polarizing film PF of the display panel 200 by an adhesive such as an optically clear adhesive (OCA) film.

The display panel 200 may be placed (or ‘disposed’) under the cover window 100. The display panel 200 may have a rectangular shape having longer sides in the first direction D1 and shorter sides in the second direction D2 in a plan view. In the display panel 200, the corners where the longer sides in the first direction D1 intersect the shorter sides in the second direction D2 may be formed at a right angle or may be rounded with a curvature. The display panel 200 may have a quadrangular shape other than a rectangle, a polygonal shape other than a quadrangular shape, a circular shape, an oval shape, or an irregular shape in a plan view.

The display panel 200 may include a display area where a plurality of emission areas that emits light is arranged, and a non-display area disposed around the display area. The non-display area may surround the display area. A plurality of display pads may be disposed in the non-display area at an edge (or ‘edge portion’) of the display panel 200.

The display panel 200 may include a substrate SUB, a display layer PAL, a sensor SENL and a polarizing film PF.

The substrate SUB may be made of an insulating material such as glass, quartz and a polymer resin. The substrate SUB may be a rigid substrate or a flexible substrate that can be bent, folded, rolled, and so on.

The display layer PAL may be disposed on the substrate SUB. The display layer PAL may be a layer including a plurality of emission areas that emit light. The display layer PAL may include a buffer film, a thin-film transistor layer on which thin-film transistors are disposed, a light-emitting layer that emits light, and an encapsulating layer for encapsulating the light-emitting layer.

The sensor SENL may be disposed on the display layer PAL. The sensor SENL may include sensor electrodes and may sense whether there is a user's touch.

The polarizing film PF may be disposed on the sensor SENL. The polarizing film PF can prevent the deterioration of image visibility of the display panel 200 due to reflection of external light. The polarizing film may include a linear polarizer and a retardation film such as a λ/4 (quarter-wave) plate. The phase retardation film may be disposed on the sensor SENL, and the linear polarizer may be disposed on the phase retardation film. The cover window 100 may be disposed on the polarizing film PF.

The panel support 300 may be located (or ‘disposed’) under the substrate SUB. The panel support 300 may be attached to the lower surface of the substrate SUB by an adhesive. The adhesive may be a pressure-sensitive adhesive (PSA). The panel support 300 may include at least one of a light-absorbing layer for absorbing light incident from an exterior, a buffer for absorbing external impact, and a heat sink for efficiently dissipating heat from the display panel 200.

The light-absorbing layer may be located under the substrate SUB. The light-absorbing layer blocks the transmission of light to prevent the elements disposed thereunder from being seen from above the display panel 200, such as the display circuit board. The light-absorbing layer may include a light-absorbing material such as a black pigment and a black dye.

The buffer may be located under the light-absorbing layer. The buffer may absorb an external impact to prevent the display panel 200 from being damaged. The buffer may be made up of (or ‘include’) a single layer or multiple layers. For example, the buffer may be formed of a polymer resin such as polyurethane, polycarbonate, polypropylene and polyethylene, or may be formed of a material having elasticity such as a rubber and a sponge obtained by foaming a urethane-based material or an acrylic-based material.

The heat sink may be located under the buffer. The heat sink may include a first heat sink layer including graphite or carbon nanotubes, and a second heat sink layer formed of a thin metal film such as copper, nickel, ferrite and silver, which can block electromagnetic waves and have high thermal conductivity.

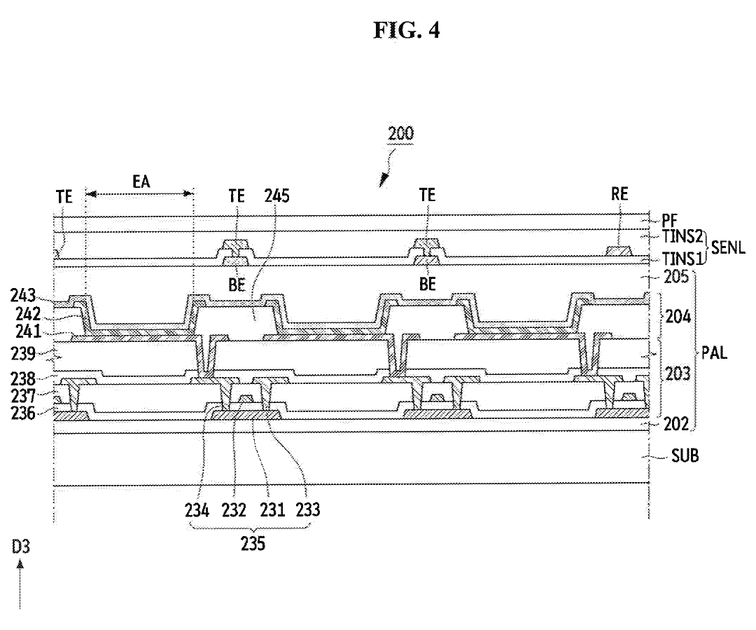

FIG. 4 is an exploded cross-sectional view of the display panel of FIG. 3.

Referring to FIG. 4, the display layer PAL may include a buffer layer 202, a thin-film transistor layer 203, a light-emitting layer 204, and an encapsulation layer 205.

The buffer layer 202 may be formed on the substrate SUB. The buffer layer 202 may be formed on the substrate SUB to protect the thin-film transistors 235 and the light-emitting elements from moisture permeating through the substrate SUB. The buffer layer 202 may be formed of a plurality of inorganic layers alternately stacked on one another. For example, the buffer layer 202 may include multiple layers in which one or more inorganic layer of a silicon oxide layer (SiOₓ), a silicon nitride layer (SiNₓ) and SiON are stacked on one another alternately. The buffer layer 202 may be eliminated.

The thin-film transistor layer 203 is formed on the buffer layer 202. The thin-film transistor layer 203 may include thin-film transistors 235, a gate insulator 236, an interlayer dielectric layer 237, a protective layer 238, and an organic layer 239.

Each of the thin-film transistor 235 may include an active layer 231, a gate electrode 232, a source electrode 233, and a drain electrode 234. In FIG. 4, the thin-film transistors 235 are implemented as top-gate transistors in which the gate electrode 232 is located above the active layer 231. It is, however, to be understood that the disclosure is not necessarily limited thereto. For example, the thin-film transistors 235 may be implemented as bottom-gate transistors in which the gate electrode 232 is located below the active layer 231, or as double-gate transistors in which the gate electrodes 232 are located above and below the active layer 231.

The active layer 231 is formed on the buffer layer 202. The active layer 231 may be formed of a silicon-based semiconductor material or an oxide-based semiconductor material. For example, the active layer 231 may be formed of polycrystalline silicon, amorphous silicon, or an oxide semiconductor. A light-blocking layer for blocking external light incident on the active layer 231 may be formed between the buffer layer 202 and the active layer 231.

The gate insulator 236 may be formed on the active layer 231. The gate insulator 236 may be formed of an inorganic layer, such as for example, a silicon oxide layer (SiOₓ), a silicon nitride layer (SiNₓ), or a multilayer thereof.

The gate electrode 232 may be formed on the gate insulator 236. The gate electrode 232 and the gate lines may include a single layer or multiple layers of one of molybdenum (Mo), aluminum (Al), chromium (Cr), gold (Au), titanium (Ti), nickel (Ni), neodymium (Nd), copper (Cu), an alloy thereof, or a combination thereof.

The interlayer dielectric layer 237 may be formed over the gate electrodes 232 and the gate lines. The interlayer dielectric layer 237 may be formed as an inorganic layer, such as for example, a silicon oxide layer (SiOₓ), a silicon nitride layer (SiNₓ), or as multiple layers thereof.

The source electrode 233 and the drain electrode 234 may be formed on the interlayer dielectric layer 237. Each of the source electrode 233 and the drain electrode 234 may be connected to the active layer 231 through a contact hole penetrating through the gate insulator 236 and the interlayer dielectric layer 237. The source electrode 233 and the drain electrode 234 may include a single layer or multiple layers of molybdenum (Mo), aluminum (Al), chromium (Cr), gold (Au), titanium (Ti), nickel (Ni), neodymium (Nd), copper (Cu), an alloy thereof, or a combination thereof.

The protective layer 238 may be formed on the source electrode 233 and the drain electrode 234 to insulate the thin-film transistors 235. The protective layer 238 may be formed of an inorganic layer, such as for example a silicon oxide layer (SiOₓ), a silicon nitride layer (SiNₓ), or a multilayer thereof.

The organic layer 239 may be formed on the protective layer 238 to provide a substantially flat surface over the thin-film transistors 235 having difference levels. The organic layer 239 may be implemented as an organic film such as an acryl resin, an epoxy resin, a phenolic resin, a polyamide resin, a polyimide resin, or a combination thereof.

The light-emitting layer 204 may be formed on the thin-film transistor layer 203. The light-emitting layer 204 may include the light-emitting elements and a bank 245.

The light-emitting elements and the bank 245 may be formed on the organic layer 239. An organic light-emitting device including an anode electrode 241, emissive layers 242 and a cathode electrode 243 may be employed as an example of the light-emitting elements.

The anode electrode 241 may be formed on the organic layer 239. The anode electrode 241 may be connected to the drain electrode 234 of the thin-film transistor 235 via a contact hole penetrating through the protective layer 238 and the organic layer 239.

The bank 245 may be formed to cover the edges (or ‘the edge portions’) of the anode electrode 241 on the organic layer 239 to define the emission areas EA of the pixels. For example, the bank 245 may define the emission areas EA of the pixels. In each of the pixels, the anode electrode 241, the emissive layer 242 and the cathode electrode 243 may be sequentially stacked on one another so that holes from the anode electrode 241 and electrons from the cathode electrode 243 may combine in the emissive layer 242 to emit light.

The emissive layers 242 are formed on the anode electrode 241 and the bank 245. The emissive layers 242 may be organic emissive layers. The emissive layers 242 may emit at least one of red light, green light, and blue light. For example, the emissive layer 242 may be a white emissive layer that emits white light. In such case, the red emissive layer, the green emissive layer and the blue emissive layer may be stacked on one another or may be formed commonly across the pixels as a common layer. The display panel 200 may further include additional color filters for representing red, green and blue colors.

The emissive layer 242 may include a hole transporting layer, a light-emitting layer, and an electron transporting layer. The emissive layer 242 may be formed in a tandem structure of two or more stacks, in which case a charge generating layer may be formed between the stacks.

The cathode electrode 243 is formed on the emissive layer 242. The cathode electrode 243 may be formed to overlap the emissive layer 242 in a plan view. The cathode electrode 243 may be a common layer formed across the pixels.

When the light-emitting layer 204 is of a top-emission type in which light is emitted toward the upper side, the anode electrode 241 may be made of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). The APC alloy is an alloy of silver (Ag), palladium (Pd) and copper (Cu). The cathode electrode 243 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the cathode electrode 243 is formed of a translucent conductive material, the light extraction efficiency can be increased by using microcavities.

When the light-emitting layer 204 is of a bottom-emission type in which light exits toward the lower side, the anode electrode 241 may be formed of a transparent conductive material (TCP) such as ITO and IZO that can transmit light, or a semi-transmissive conductive material such as magnesium (Mg), silver (Ag) and an alloy of magnesium (Mg) and silver (Ag). The cathode electrode 243 may be made of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). When the anode electrode 241 is formed of a translucent conductive material, the light extraction efficiency can be increased by using microcavities.

The encapsulation layer 205 may be formed on the light-emitting layer 204. The encapsulation layer 205 may serve to prevent permeation of oxygen or moisture into the emissive layer 242 and the cathode electrode 243. To this end, the encapsulation layer 205 may include at least one inorganic film. The inorganic film may be made of silicon nitride, aluminum nitride, zirconium nitride, titanium nitride, hafnium nitride, tantalum nitride, silicon oxide, aluminum oxide, titanium oxide, or a combination thereof. The encapsulation layer 205 may further include at least one organic film. The organic film may have a sufficient thickness to prevent particles from permeating into the encapsulation layer 205 and entering the emissive layer 242 and the cathode electrode 243. The organic film may include one of an epoxy, an acrylate, urethane acrylate, or a combination thereof.

The sensor SENL may be formed on the encapsulation layer 205. When the sensor SENL may be formed directly on the encapsulation layer 205, the thickness of the display device 10 can be reduced as compared to a display device in which a separate touch panel is attached on the encapsulation layer 205.

The sensor SENL may include sensor electrodes for sensing a user's touch by capacitive sensing, and touch lines for connecting the pads with the sensor electrodes. For example, the sensor SENL can sense a user's touch by self-capacitance sensing or mutual capacitance sensing. In the example shown in FIG. 4, the sensor SENL may include up of two layers including driving electrodes TE, sensing electrodes RE and bridge electrodes BE connecting between the driving electrodes TE for mutual capacitance sensing.

The bridge electrodes BE may be formed on the encapsulation layer 205. The bridge electrodes BE may include, but is not necessarily limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). For example, the bridge electrodes BE may include a single layer of molybdenum (Mo), titanium (Ti), copper (Cu), aluminum (Al), ITO, or a combination thereof.

A first sensing insulating layer TINS1 may be formed over the bridge electrodes BE. The first sensing insulating film TINS1 may be formed of an inorganic film, such as for example, a silicon nitride layer, a silicon oxynitride layer, a silicon oxide layer, a titanium oxide layer, an aluminum oxide layer, or a combination thereof.

The driving electrodes TE and the sensing electrodes RE may be formed on the first sensing insulating film TINS1. The driving electrode TE and the sensing electrode RE may be formed as, but is not necessarily limited to, a stack structure of aluminum and titanium (Ti / Al / Ti), a stack structure of aluminum and ITO (ITO / Al / ITO), an APC alloy and a stack structure of APC alloy and ITO (ITO / APC / ITO). For example, the driving electrodes TE and the sensing electrodes RE may include a single layer of molybdenum (Mo), titanium (Ti), copper (Cu), aluminum (Al), ITO, or a combination thereof.

Contact holes may be formed in the first sensing insulating layer TINS1 which penetrate the first sensing insulating layer TINS1 to expose the bridge electrodes BE. The driving electrodes TE may be connected to the bridge electrodes BE through the contact holes.

A second sensing insulating layer TINS2 may be formed over the driving electrodes TE and the sensing electrodes RE. The second sensing insulating layer TINS2 may provide a substantially flat surface over the driving electrodes TE, the sensing electrodes RE and the bridge electrodes BE which have different heights. The second sensing insulating layer TINS2 may be formed of an organic layer such as an acryl resin, an epoxy resin, a phenolic resin, a polyamide resin, a polyimide resin, or a combination thereof.

The bridge electrodes BE connecting between the adjacent driving electrodes TE may be located on the encapsulation layer 205, and the driving electrodes TE and the sensing electrodes RE may be located on the first sensing insulating layer TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The polarizing film PF may be disposed on the second sensing insulating layer TINS2 to prevent the deterioration of image visibility of the display panel 200 due to reflection of external light.

Referring back to FIGS. 2 and 3, the protective coating layer 400 can protect at least a part of the display panel 200. For example, the protective coating layer 400 can protect a part of the lower surface of the substrate SUB of the display panel 200. The substrate SUB of the display panel 200 may be divided into a first area supported (e.g., ‘overlapped in a plan view’) by the panel support 300, and a second area not supported (e.g., ‘not overlapped in a plan view’) by the panel support 300. The protective coating layer 400 may be disposed in the second area of the display panel 200 to protect the second area of the display panel 200. The lower surface of the protective coating layer 400 and the lower surface of the panel support 300 may be coplanar. In some embodiments, the thickness of the protective coating layer 400 in the third direction D3 may be substantially equal to the thickness of the panel support 300 in the third direction D3.

The protective coating layer 400 may be formed on the lower surface of the second area of the substrate SUB by a screen printing process. For example, the protective coating layer 400 may be formed by applying SP (or ‘screen print’) ink onto the lower surface of the second area of the substrate SUB via a screen printing process. The protective coating layer 400 can protect the second area of the substrate SUB from moisture, electromagnetic waves, shock, etc., from an exterior.

The test coating layer 500 may be arranged on the lower surface of the panel support 300. There may be a plurality of test coating layers 500. The test coating layers 500 may be arranged while being spaced apart from one another along an edge (or ‘edge portion’) of the panel support 300. For example, if the shape of the panel support 300 is of a rectangular shape in a plan view, there may be four test coating layers 500, which may be located at the corners (or ‘corner portions’) of the panel support 300, respectively, in a plan view. Since the test coating layers 500 are arranged at the corners of the panel support 300, respectively, in a plan view, at least one of the sides of the test coating layer 500 may be located at the boundary between the panel support 300 and the protective coating layer 400.

The test coating layers 500 may be made of the same material as the protective coating layer 400 and may be arranged on the lower surface of the panel support 300 via the same process as the protective coating layer 400. For example, the test coating layers 500 may be arranged on the lower surface of the panel support 300 via a screen printing process. The test coating layers 500 may be formed by applying SP ink onto the lower surface of the panel support 300 via a screen printing process.

FIG. 5 is a bottom view showing another example of the display device shown in FIG. 2. FIG. 6 is a cross-sectional view taken along line B – B' of FIG. 5.

Referring to FIGS. 5 and 6, the test coating layer 500 may be disposed on the lower surface of the cover window 100. There may be a plurality of test coating layers 500. The test coating layers 500 may be arranged while being spaced apart from one another along an edge of the cover window 100. For example, if the shape of the cover window 100 is of a rectangular shape in a plan view, there may be four test coating layers 500, which may be located at the corners (or ‘corner portions’) of the cover window 100, respectively, in a plan view. Since the test coating layers 500 are arranged at the corners of the cover window 100, respectively, in a plan view, at least one of the sides of the test coating layer 500 may be located at (or ‘be flush with’) the sides of the cover window 100 in a plan view.

The test coating layers 500 and the protective coating layer 400 may include a same material. The test coating layers 500 may be arranged on the lower surface of the cover window 100. The test coating layer 500 and the protective coating layer 400 may be formed by a same process. For example, the test coating layers 500 may be arranged on the lower surface of the cover window 100 via a screen printing process. The test coating layers 500 may be formed by applying SP (or ‘screen printing’) ink onto the lower surface of the cover window 100 via a screen printing process.

According to embodiments of the disclosure, the display device may include a display panel 200 that may include a substrate SUB mounted on a panel support 300 to protect a first area of the display panel. However the panel support 300 may not cover edge portions corresponding to a second area of the substrate of the display panel 200. Therefore a protective coating layer 400 may be disposed on a lower surface of the edge portions of the substrate SUB to correspond to a second area of the substrate SUB. The protective coating layer 400 may be formed by a screen printing technique. A test coating layer 500 may be formed simultaneously with the protective coating layer 400. In a first embodiment of FIGS. 2-3, the test coating layer 500 may be formed at corner portions on a lower surface of the panel support 300, and in a second embodiment of FIGS. 5-6, the test coating layer 500 may be formed at corner portions on a lower side of the cover window 100.

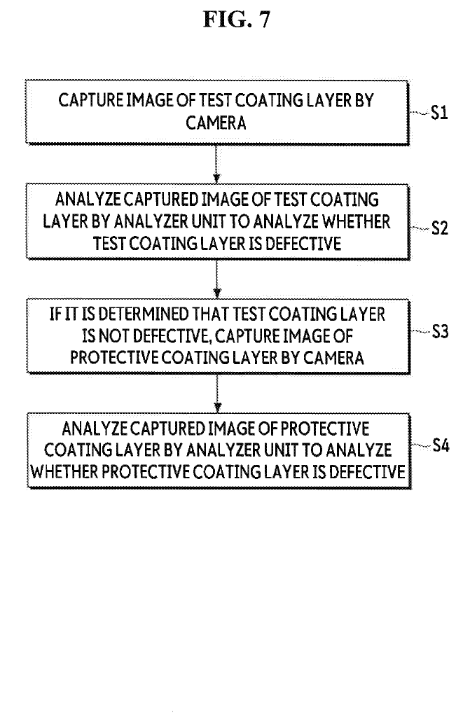

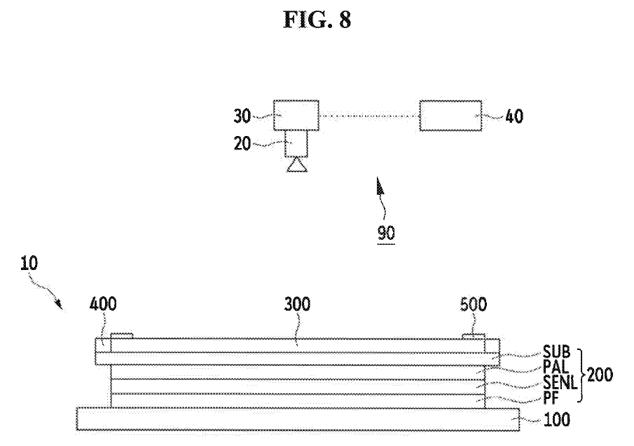

FIG. 7 is a flowchart for illustrating a method for inspecting a display device according to an embodiment of the disclosure. FIG. 8 is a view showing an inspector inspecting a display device. In FIG. 8, the test coating layers 500 may be disposed on the panel support 300 as in FIGS. 2 and 3.

Referring to FIGS. 7 and 8, a method for inspecting a display device 10 according to an embodiment of the disclosure may include capturing, by a camera 20 of an inspector 90, an image of a test coating layer 500 in step S1, analyzing, by an analyzer 40 of the inspector 90, the captured image of the test coating layer 500 to determine whether the test coating layer 500 is defective in step S2, capturing, by the camera 20, an image of a protective coating layer 400 in step S3, and analyzing, by the analyzer 40, the captured image of the protective coating layer 400 to determine whether the protective coating layer 400 is defective in step S4.

An inspector 90 for inspecting the display device 10 will be described prior to describing the method for inspection a display device 10.

The inspector 90 may include a camera 20, an actuator (or ‘a moving module’) 30, and an analyzer 40.

The camera 20 may overlap the display device 10 such that it faces the panel support 300 of the display device 10. For example, when the display device 10 is located above an inspector 90 so that the cover window 100 comes into contact with the inspector 90, the camera 20 may be disposed above the display device 10 as shown in FIG. 8. The camera 20 may be a typical optical camera and may be disposed above the display device 10 in FIG. 8 to capture images of the protective coating layer 400 and the test coating layer 500. The camera 20 may transmit the captured images of the protective coating layer 400 and the test coating layer 500 to the analyzer 40.

The actuator 30 may move the camera 20. The actuator 30 may be an actuator such as a linear motor and a step motor. The actuator 30 may be connected to the camera 20 to move the camera 20 horizontally above the display device 10 in FIG. 8.

The analyzer 40 may analyze the images of the protective coating layer 400 and the test coating layer 500 captured by the camera 20 to determine whether the protective coating layer 400 and the test coating layer 500 are defective. For example, the analyzer 40 may compare the correct images of the protective coating layer 400 and the test coating layer 500 with the captured images of the protective coating layer 400 and the test coating layer 500 captured by the camera 20 to determine whether the protective coating layer 400 and the test coating layer 500 are defective.

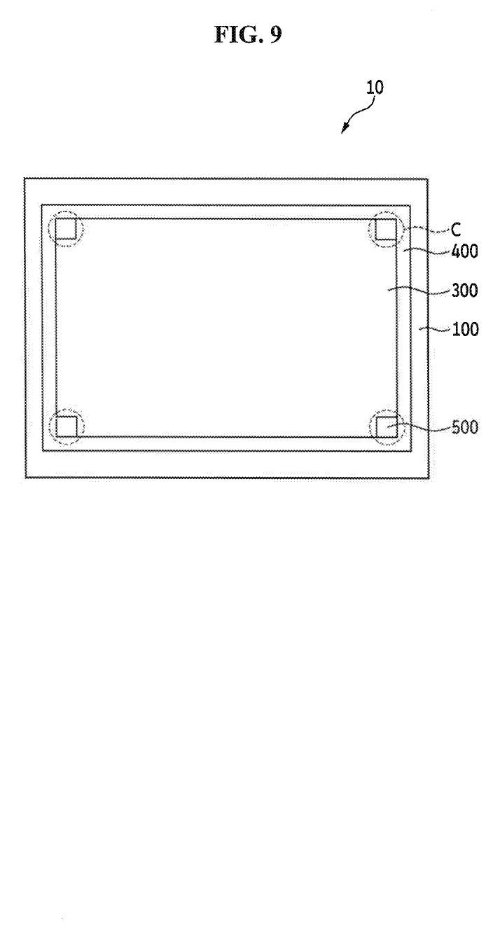

FIG. 9 is a view showing capture areas where the camera of the inspector may capture images of test coating layers of a display device.

Referring to FIG. 9, the capturing, by the camera 20, of the images of the test coating layers 500 may include moving the camera 20 using an actuator 30 so that the camera 20 passes over each of the test coating layers 500. When the test coating layers 500 are arranged on the panel support 300, the camera 20 may temporarily stop above a capture area C to capture the image of each of the test coating layers 500. According to this embodiment, the camera 20 may be moved by the actuator 30 to capture the image of each of the test coating layers 500, but the disclosure is not necessarily limited thereto. The camera 20 may be located at a certain distance from the display device 10 to capture all the images of the test coating layers 500 at a single point in time. The images of the test coating layers 500 captured by the camera 20 may be transmitted to the analyzer 40.

The analyzing, by the analyzer 40, of the captured images of the test coating layers 500 to determine whether the test coating layers 500 are defective may include comparing, by the analyzer 40, correct images of the test coating layers 500 stored in advance with the images of the test coating layers 500 captured by the camera 20 to determine whether the test coating layers 500 are defective.

If it is determined by the analyzer 40 that the test coating layers 500 are not defective, the method may also include capturing, by the camera 20, an image of the protective coating layer 400.

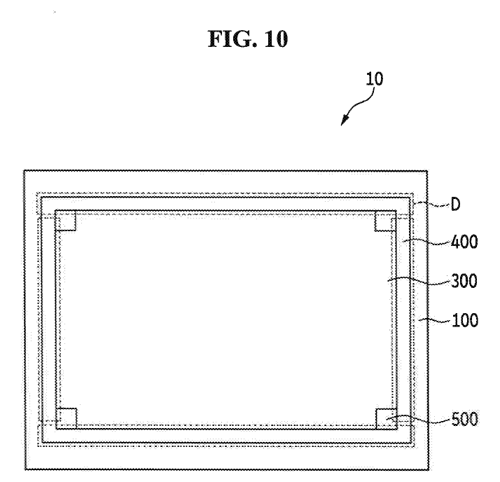

FIG. 10 is a view showing capture areas where the camera of the inspector may capture images of a protective coating layer of a display device.

Referring to FIG. 10, the capturing, by the camera 20, of images of the protective coating layer 400 may include moving the camera 20 by the actuator 30 along the protective coating layer 400 from above the protective coating layer 400. The camera 20 may move along the protective coating layer 400 and capture the images of the protective coating layer 400 at the capture areas D. According to this embodiment, the camera 20 may be moved by the actuator 30 to capture the images of the protective coating layer 400, but the disclosure is not necessarily limited thereto. The camera 20 may be located at a certain distance from the display device 10 to capture all the images of the capture areas D of the protective coating layer 400 at a point in time. The images of the protective coating layer 400 captured by the camera 20 may be transmitted to the analyzer 40.

The analyzing, by the analyzer 40, of the captured images of the protective coating layer 400 to determine whether the protective coating layer 400 is defective may include comparing, by the analyzer 40, a correct image of the protective coating layer 400 stored in advance with the images of the protective coating layer 400 captured by the camera 20 to determine whether the protective coating layer 400 is defective.

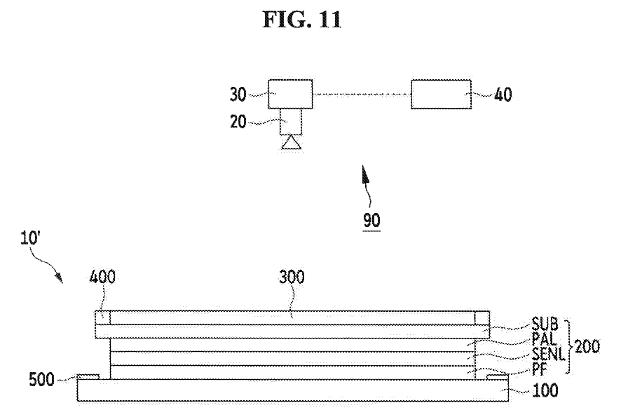

FIG. 11 is a view showing another example of FIG. 8.

To the extent that elements of the inspector 90 are not described in detail with respect to FIG. 11, it may be understood that aside from the positions of the test coating layers 500, the elements of the inspector 90 of FIG. 11 are at least similar to corresponding elements of the inspector 90 that have been previously described in FIG. 8 of the disclosure. In FIG. 11, the test coating layers 500 may be arranged on a cover window 100 as per FIGS. 5-6.

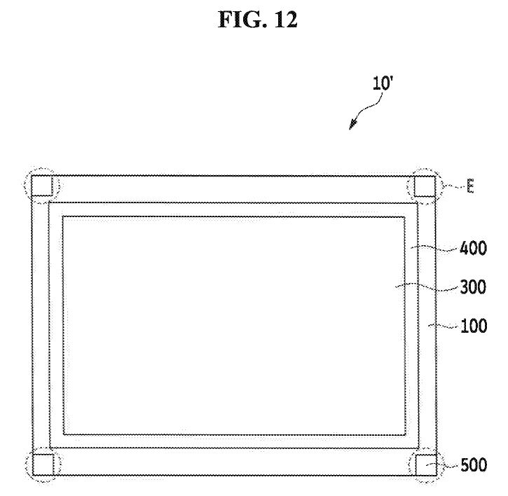

FIG. 12 is a view showing capture areas where the camera of the inspector may capture images of test coating layers of a display device in the example of FIG. 11.

Referring to FIG. 12, the capturing, by the camera 20, the images of the test coating layers 500 may include moving the camera 20 by an actuator 30 so that the camera 20 passes over each of the test coating layers 500. When the test coating layers 500 are arranged on the cover window 100, the camera 20 may temporarily stop above a capture area E to capture the image of each of the test coating layers 500. According to this embodiment, the camera 20 may be moved by the actuator 30 to capture the image of each of the test coating layers 500, but the disclosure is not necessarily limited thereto. The camera 20 may be located at a certain distance from the display device 10’ to capture all the images of the test coating layers 500 simultaneously at a single point in time. The images of the test coating layers 500 captured by the camera 20 may be transmitted to the analyzer 40.

The analyzer 40 may analyze the captured images of the test coating layers 500 to determine whether the test coating layers 500 are defective by comparing correct images of the test coating layers 500 stored in advance with the images of the test coating layers 500 captured by the camera 20.

If it is determined by the analyzer 40 that the test coating layers 500 are not defective, the method may also include capturing, by the camera 20, an image of the protective coating layer 400.

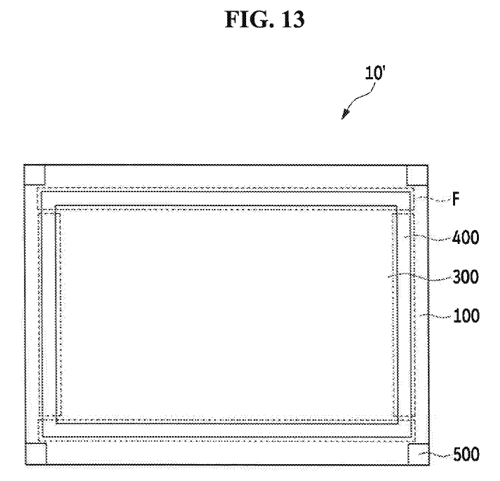

FIG. 13 is a view showing capture areas where the camera of the inspector may capture images of a protective coating layer of a display device in the example of FIG. 11.

Referring to FIG. 13, the capturing, by the camera 20, the images of the protective coating layer 400 may include moving the camera 20 along the protective coating layer 400 from above the protective coating layer 400 by the actuator 30. The camera 20 may move along the protective coating layer 400 and capture the images of the protective coating layer 400 at the capture areas F while moving by the actuator 30. According to this embodiment, the camera 20 is moved by the actuator 30 to capture the images of the protective coating layer 400, but the disclosure is not necessarily limited thereto. The camera 20 may be located at a certain distance from the display device 10’ to capture all the images of the capture areas F of the protective coating layer 400 at a point in time. The images of the protective coating layer 400 captured by the camera 20 may be transmitted to the analyzer 40.

The analyzer 40 may analyze the captured images of the protective coating layer 400 to determine whether the protective coating layer 400 is defective by comparing a correct image of the protective coating layer 400 stored in advance with the images of the protective coating layer 400 captured by the camera 20.

The method for inspecting a display device 10’ may include first inspecting test coating layers 500 prior to inspecting a protective coating layer 400. Since the test coating layers 500 and the protective coating layer 400 are formed using a same material and by a same process, if the test coating layer 500 is defective, it is very highly likely that the protective coating layer 400 is also defective. Therefore, it is first analyzed whether the test coating layers 500 are defective and, if it is determined that a test coating layer 500 is defective, it is determined that the display device 10’ is defective. In this manner, it is possible to more efficiently determine whether or not the display device 10’ is defective.

According to embodiments, a method of inspecting the display device by an inspector 90 may involve determining whether there are defects in the protective coating layer 400. This may be gleaned by determining whether defects are present in the test coating layers 500. A camera 20 may capture images of the test coating layers 500 and an analyzer 40 may compare the captured images with images of a non-defective test coating layer preloaded into the inspector to determine whether the test coating layers are defective. If the test coating layers 500 are determined not to be defective, the camera 20 may capture images of the protective coating layer 400 and compare the captured image with images of a non-defective protective coating layer to determine whether the protective coating layer 400 on the display panel 200 is defective. If the test coating layers 500 are determined to be defective, the inspection process may conclude that the protective coating layer 400 is also defective.

The display device according to the embodiment of the disclosure may be applied to a variety of electronic devices. An electronic device according to an embodiment may include the display device described above, and may further include a module or device having additional features in addition to the display device.

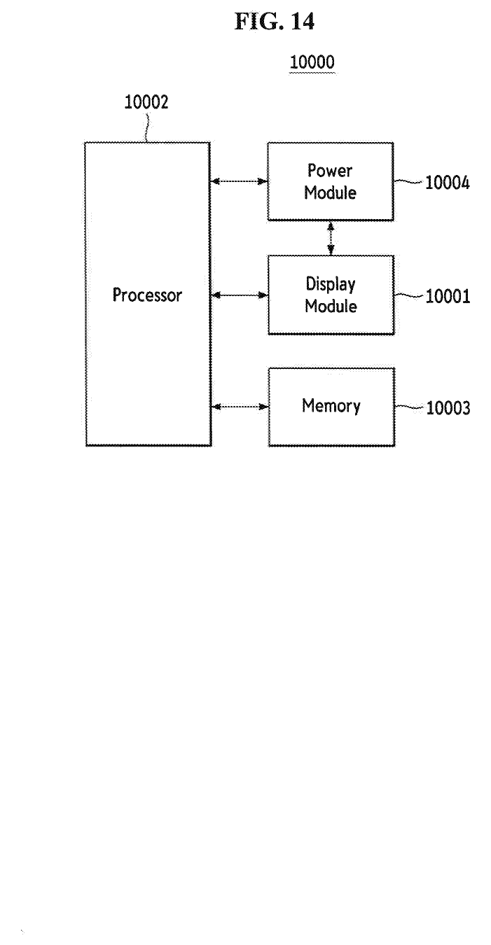

FIG. 14 is a block diagram of an electronic device according to an embodiment of the disclosure.

Referring to FIG. 14, an electronic device 10000 according to an embodiment of the disclosure may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), and a controller.

The memory 10003 may store data information required for the operation of the processor 10002 or the display module 10001. When the processor 10002 executes an application stored in the memory 10003, an image data signal and/or an input control signal may be transmitted to the display module 10001. The display module 10001 may process the received signal and output image information through a display screen.

The power module 10004 may include a power supply module such as a power adapter and a battery device, and a power conversion module that converts the power supplied by the power supply module to generate power required for the operation of the electronic device 10000.

At least one of the elements of the electronic device 10000 described above may be included in the display devices according to the embodiments described above. Some of the individual modules functioning as a single module may be included in the display device while some others may be provided separately from the display device. For example, the display device may include the display module 10001, the processor 10002, and the memory 10003, while the power module 10004 may be implemented as another device disposed inside the electronic device 10000 but external to the display device.

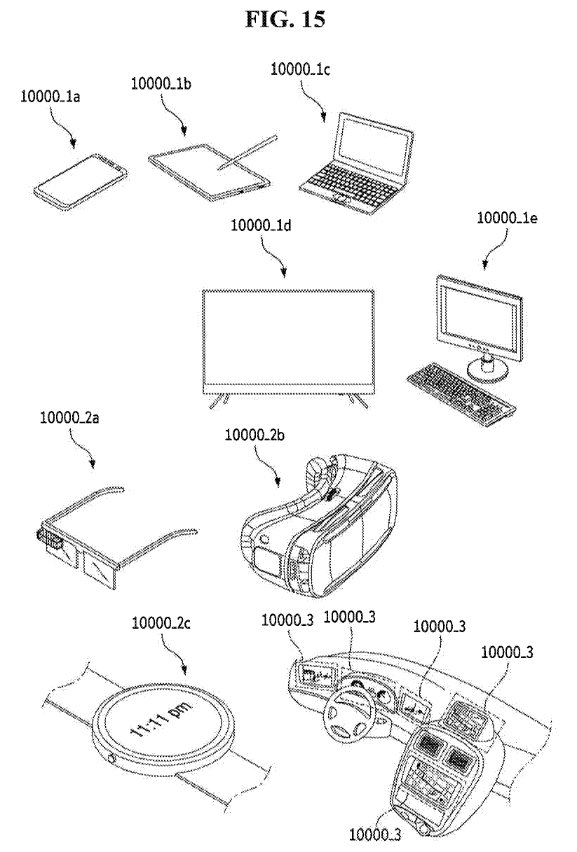

FIG. 15 is a view showing electronic devices according to a variety of embodiments of the disclosure.

Referring to FIG. 15, a variety of electronic devices employing display devices according to embodiments may include not only image display electronic devices such as a smart phone 10000_1a, a tablet 10000_1b, a laptop computer 10000_1c, a TV 10000_1d and a computer monitor 10000_1e, but also wearable electronic devices including display modules such as smart glasses 10000_2a, a head-mounted display 10000_2b and a smart watch 10000_2c, and electronic devices for vehicles 10000_3 including display modules such as a center information display (CID) disposed on the dashboard, the center fascia and the dashboard of a vehicle, and a room mirror display.

It should be understood, however, that the aspects and features of embodiments of the disclosure are not restricted to the one set forth herein. The above and other aspects of the disclosure will become more apparent to one of ordinary skill in the art to which the disclosure pertains by referencing the claims, with equivalents thereof to be included therein.

What is claimed is:

1. A display device comprising:
a display panel;
a cover window disposed on the display panel;
a panel support, the display panel being disposed on the panel support;
a protective coating layer configured to protect at least a part of the display panel; and
at least one test coating layer disposed on at least one of the cover window and the panel support.

2. The display device of claim 1, wherein
the display panel is divided into a first area that overlaps the panel support in a plan view and a second area that does not overlap the panel support in a plan view, and
the protective coating layer is configured to protect the second area of the display panel.

3. The display device of claim 2, wherein the at least one test coating layer is disposed on the panel support.

4. The display device of claim 3, wherein
the at least one test coating layer comprises a plurality of test coating layers, and
the plurality of test coating layers are disposed along an edge portion of the panel support while being spaced apart from one another.

5. The display device of claim 4, wherein
the panel support has a polygonal shape having a plurality of sides in a plan view, and
the plurality of test coating layers are disposed at corner portions of the panel support, respectively.

6. The display device of claim 2, wherein the at least one test coating layer is disposed on the cover window.

7. The display device of claim 6, wherein
the at least one test coating layer comprises a plurality of test coating layers, and
the plurality of test coating layers are disposed along an edge portion of the cover window while being spaced apart from one another.

8. The display device of claim 7, wherein
the cover window has a polygonal shape having a plurality of sides in a plan view, and
the plurality of test coating layers are disposed at corner portions of the cover window, respectively.

9. The display device of claim 2, wherein a lower surface of the protective coating layer and a lower surface of the panel support are coplanar.

10. The display device of claim 1, wherein the protective coating layer and the at least one test coating layer are comprised of a same material.

11. A method for inspecting a display device, the method comprising:
capturing an image of at least one test coating layer by a camera of an inspector;
determining whether the at least one test coating layer is defective by analyzing the captured image of the at least one test coating layer by an analyzer of the inspector;
capturing an image of a protective coating layer by the camera; and
determining whether the protective coating layer is defective by analyzing the captured image of the protective coating layer by the analyzer.

12. The method of claim 11, wherein the inspector further comprises an actuator that moves the camera.

13. The method of claim 12, wherein
the at least one test coating layer comprises a plurality of test coating layers,
the plurality of test coating layers are spaced apart from one another, and
the capturing of the image of the at least one test coating layer comprises moving the camera over each of the plurality of test coating layers in a plan view by the actuator.

14. The method of claim 12, wherein
the display device comprises a display panel,
the protective coating layer is disposed along an edge portion of the display panel, and
the capturing of the image of the protective coating layer comprises moving the camera over the protective coating layer in a plan view by the actuator.

15. The method of claim 11, wherein the capturing of the image of the protective coating layer is conducted upon determination that the at least one test coating layer is not defective.

16. An electronic device comprising:
a display panel;
a cover window disposed on the display panel;
a panel support, the display panel is disposed on the panel support in a plan view;
a protective coating layer configured to protect at least a part of the display panel; and
at least one test coating layer disposed on at least one of the cover window and the panel support.

17. The electronic device of claim 16, wherein
the display panel is divided into a first area that overlaps the panel support in a plan view and a second area that does not overlap the panel support in a plan view, and
the protective coating layer is configured to protect the second area of the display panel.

18. The electronic device of claim 17, wherein
the at least one test coating layer comprises a plurality of test coating layers, and
the plurality of test coating layers are disposed along an edge portion of the panel support while being spaced apart from one another.

19. The electronic device of claim 17, wherein
the at least one test coating layer comprises a plurality of test coating layers, and
the plurality of test coating layers are disposed along an edge portion of the cover window while being spaced apart from one another.

20. The electronic device of claim 16, further comprising:
at least one processor;
a memory in which data of at least one of the display panel and the at least one processor is stored; and
a power module configured to supply power to the display panel, the at least one processor and the memory.
